(19) United States
(12) Patent Application Publication
(10) Pub. No.: US 2026/0082845 A1
(43) Pub. Date: Mar. 19, 2026

(54) SUBSTRATE PROCESSING APPARATUS

(71) Applicant: SEMES CO., LTD., Cheonan-si (KR)

(72) Inventors: Min Hee CHO, Suwon-si (KR); Chun Woo PARK, Yongin-si (KR); Dong Jin SHIN, Suwon-si (KR); Jae Hyeok YU, Hwaseong-si (KR); Yeong Seok LIM, Suwon-si (KR); Byung Hwi KIM, Hwaseong-si (KR); Hyeong Soo PARK, Yongin-si (KR)

(73) Assignee: SEMES CO., LTD., Cheonan-si (KR)

(21) Appl. No.: 19/333,713

(22) Filed: Sep. 19, 2025

(30) Foreign Application Priority Data
Sep. 19, 2024 (KR) 10-2024-0126543

(51) Int. Cl. H01L 21/67; B01F 25/00; B01F 35/221; B01F 35/71; B01F 101/24

(52) U.S. Cl. CPC H10P 72/0414; B01F 25/105; B01F 35/2211; B01F 35/2215; B01F 35/718051; B01F 2101/24

(57) ABSTRACT

Disclosed is a substrate processing apparatus that is capable of preventing defects from occurring in a substrate processing process when a substrate is processed by supplying a temperature and concentration controlled treatment solution to the substrate. According to an exemplary embodiment, the substrate processing apparatus includes a mixing manifold, and in the mixing manifold, first to fourth inlet lines are connected in parallel with an outlet line, and a high-flow rate liquid is supplied toward a low-flow rate liquid.

### CROSS-REFERENCE TO RELATED APPLICATION

This application claims priority to and the benefit of Korean Patent Application No. 10-2024-0126543 filed in the Korean Intellectual Property Office on Sep. 19, 2024, the entire contents of which are incorporated herein by reference.

### TECHNICAL FIELD

The present invention relates to a substrate processing apparatus, and more particularly, to a substrate processing apparatus that processes a substrate by supplying a temperature and concentration controlled treatment solution to the substrate.

### BACKGROUND ART

The semiconductor process includes a process of cleaning thin films, foreign substances, particles, and the like on a substrate. These processes are performed by placing a substrate on the spin head so that a pattern surface faces up or down, supplying a treatment solution onto the substrate in a state in which the spin head is rotated, and then drying a wafer.

The treatment solution supplied onto the substrate may be provided as a mixed liquid in which a plurality of liquids is mixed. Further, the plurality of liquids may be mixed in a mixing manifold 100. FIG. 1 is a diagram schematically illustrating an exemplary embodiment of an existing mixing manifold 100. Referring to FIG. 1, the mixing manifold 100 includes a body 110 having a space therein, a plurality of inlet ports 121, 122, 123 and 124 individually coupled to a plurality of supply lines 131, 132, 133, and 134 to supply a plurality of liquids to the body, and an outlet port 140 through which the mixed liquid is delivered to the outside. The liquid supplied through the plurality of inlet ports 121, 122, 123 and 124 is mixed in the body 110 to form a treatment solution. Then, the formed treatment solution is supplied to the substrate through the outlet port 140.

The plurality of inlet ports 121, 122, 123 and 124 of the mixing manifold 100 may be formed in a row in the longitudinal direction of the body 110. The liquid supplied through the plurality of inlet ports 121, 122, 123 and 124 is mixed while flowing in the longitudinal direction of the body 110. Accordingly, a flow path formed in the body is provided differently for each liquid supplied to each of the inlet ports 121, 122, 123 and 124.

In this mixing process, when a high-flow rate liquid is supplied through the inlet port 124 close to the outlet port 140 and a low-flow rate liquid is supplied through the inlet port 121 far from the outlet port, interference may occur in the supply of the low-flow rate liquid by the high-flow rate liquid. Such interference may prevent the low-flow rate liquid from being normally supplied, causing a problem that the low-flow rate liquid remains in at least a portion 110a of the path of the low-flow rate liquid in the body 110. It may also interfere with the mixing of the low-flow rate liquid and the high-flow rate liquid at a set concentration.

Furthermore, even if a low-flow liquid is changed to be supplied through the inlet port 124 close to the outlet port 140 and a high-flow liquid is changed to be supplied through the inlet port 121 far from the outlet port 140, when the temperature of the treatment solution is adjusted through the high-flow liquid, the temperature changes as the time for the high-flow liquid to remain in the body 110 increases, which is disadvantageous to stabilizing the temperature of the treatment solution.

When the treatment solution is not formed at the set temperature and concentration due to the above problem, a defect may occur in the process of processing the substrate.

### SUMMARY OF THE INVENTION

The present invention has been made in an effort to provide a substrate processing apparatus capable of preventing defects from occurring in a substrate processing process when a substrate is processed with a treatment solution.

The present invention has also been made in an effort to provide a substrate processing apparatus capable of efficiently mixing a plurality of liquids.

The present invention has also been made in an effort to provide a substrate processing apparatus capable of stably providing a concentration of a treatment solution.

The present invention has also been made in an effort to provide a substrate processing apparatus capable of stably providing a temperature of a treatment solution.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a processing chamber for processing a substrate; and a treatment solution supply unit for supplying a treatment solution to the processing chamber, wherein the treatment solution supply unit includes: a first supply line for supplying a first liquid; a second supply line for supplying a second liquid; and a mixing manifold for producing the treatment solution by mixing the first liquid and the second liquid; and a treatment solution supply line for supplying the treatment solution from the mixing manifold to the processing chamber, the mixing manifold includes a body that has a buffer space therein and is formed with a first inlet flow path, a second inlet flow path, and an outlet flow path, the first inlet flow path connects the first supply line and the buffer space, the second inlet flow path connects the second supply line and the buffer space, the outlet flow path connects the buffer space and the treatment solution supply line, and the first inlet flow path includes: a first inlet part through which the first liquid is introduced from the first supply line; and a first outlet part through which the first liquid flows out into the buffer space, the inlet part and the second inlet flow path are formed parallel to the outlet flow path, and the outlet part may be formed to be inclined with respect to the outlet flow path.

According to the exemplary embodiment of the present invention, wherein the treatment solution supply unit further may includes; a first valve that is installed in the first supply line and adjusts a flow rate of the first liquid; and a second valve that is installed in the second supply line and adjusts a flow rate of the second liquid, and the apparatus further comprises a controller for controlling the first valve and the second valve so that the first liquid has a lower flow rate than the second liquid.

According to the exemplary embodiment of the present invention, wherein the treatment solution supply unit further includes a third supply line for supplying a third liquid, the body is further formed with a third inlet flow path connected to the third supply line, and the third inlet flow path may be formed parallel to the outlet flow path.

According to the exemplary embodiment of the present invention, wherein the treatment solution supply unit further includes a third valve that is installed in the third supply line and adjusts a flow rate of the third liquid, and the controller may controls the third valve so that the third liquid has a lower flow rate than the first liquid.

According to the exemplary embodiment of the present invention, wherein the third inlet flow path may be formed to be adjacent to the second inlet flow path.

According to the exemplary embodiment of the present invention, wherein the treatment solution supply unit further includes a fourth supply line for supplying a fourth liquid, the body is further formed with a fourth inlet flow path connected to the fourth supply line, and the fourth inlet flow path includes: a second inlet part through which the fourth liquid is introduced from the fourth supply line; and a second outlet part through which the fourth liquid flows out into the buffer space, the second inlet part is formed parallel to the outlet flow path, and the first outlet part and the second outlet part may be formed to be inclined toward the outlet flow path.

According to the exemplary embodiment of the present invention, wherein the treatment solution supply unit further includes a fourth valve that is installed in the fourth supply line and adjusts a flow rate of the fourth liquid, and the controller may controls the fourth valve so that the fourth liquid has a lower flow rate than the third liquid.

According to the exemplary embodiment of the present invention, wherein the body includes a first sidewall and a second sidewall defining the buffer space, the first sidewall is a wall facing the second sidewall, the first inlet flow path, the second inlet flow path, the third inlet flow path, and the fourth inlet flow path are formed on the first sidewall, and the outlet flow path may be formed on the second sidewall.

According to the exemplary embodiment of the present invention, wherein the first liquid is deionized water, and the second liquid may be chemical.

According to the exemplary embodiment of the present invention, wherein the chemical may be hydrogen fluoride.

According to the exemplary embodiment of the present invention, wherein the first liquid and the fourth liquid are deionized water, the second liquid is ammonium hydroxide (NH₄OH), the third liquid is hydrogen peroxide solution (H₂O₂), and the fourth liquid may has a higher temperature than the first liquid.

An exemplary embodiment of the present disclosure, an apparatus for processing a substrate, the apparatus comprising: a processing chamber for processing a substrate; and a treatment solution supply unit for supplying a treatment solution to the processing chamber, wherein the treatment solution supply unit includes: a first supply line for supplying deionized water; a second supply line for supplying ammonium hydroxide; a third supply line for supplying hydrogen peroxide solution; and a mixing manifold for producing the treatment solution by mixing the deionized water, the ammonium hydroxide, and the hydrogen peroxide solution; and a treatment solution supply line for supplying the treatment solution from the mixing manifold to the processing chamber, and the mixing manifold includes a body that has a buffer space therein and is formed with a first inlet flow path, a second inlet flow path, a third inlet flow path, and an outlet flow path, the first inlet flow path connects the first supply line and the buffer space, the second inlet flow path connects the second supply line and the buffer space, the third inlet flow path connects the third supply line and the buffer space, the outlet flow path connects the buffer space and the treatment solution supply line, and the first inlet flow path includes: a first inlet part through which the deionized water is introduced from the first supply line; and a first outlet part through which the deionized water flows out into the buffer space, the inlet unit, the second inlet flow path, and the third inlet flow path are formed in parallel with the outlet flow path, and the outlet part may be formed to be inclined with respect to the outlet flow path.

According to the exemplary embodiment of the present invention, the apparatus may further include a controller, wherein the treatment solution supply unit includes: a first valve that is installed in the first supply line and adjusts a flow rate of the deionized water; a second valve that is installed in the second supply line and adjusts a flow rate of the ammonium hydroxide; and a third valve that is installed in the third supply line and adjusts a flow rate of the hydrogen peroxide solution, and the controller may controls the first valve, the second valve, and the third valve so that a flow rate of the deionized water is greater than the ammonium hydroxide and the hydrogen peroxide solution.

According to the exemplary embodiment of the present invention, wherein the third inlet line and the second inlet line may be formed adjacent to each other.

According to the exemplary embodiment of the present invention, wherein the body includes a first sidewall and a second sidewall defining the buffer space, the first sidewall is a wall facing the second sidewall, the first inlet flow path, the second inlet flow path, and the third inlet flow path are formed on the first sidewall, and the outlet flow path may be formed on the second sidewall.

According to the exemplary embodiment of the present invention, wherein distances between the first inlet line, the second inlet line, and the third inlet line and the outlet line may be provided equally.

According to the exemplary embodiment of the present invention, wherein the treatment solution supply unit further includes a temperature adjusting member that adjusts a temperature of the deionized water, and the controller may controls a temperature of the treatment solution by adjusting the temperature of the deionized water by controlling the temperature adjusting member.

An exemplary embodiment of the present disclosure, an apparatus for processing a substrate, the apparatus comprising: a processing chamber for processing a substrate; a treatment solution supply unit for supplying a treatment solution to the processing chamber; and a controller, wherein the treatment solution supply unit includes: a first supply line through which a first liquid is supplied, and in which a first valve is installed to adjust a flow rate of the first liquid; a second supply line through which a second liquid is supplied, and in which a second valve is installed to adjust a flow rate of the second liquid; a third supply line through which a third liquid is supplied, and in which a third valve is installed to adjust a flow rate of the third liquid; a fourth supply line through which a fourth liquid is supplied, and in which a fourth valve is installed to adjust a flow rate of the fourth liquid; and a mixing manifold connected to the first to fourth supply lines, the mixing manifold includes a body having a space therein, the body includes: a first inlet flow path connected to the first supply line; a second inlet flow path connected to the second supply line; a third inlet flow path connected to the third supply line; a fourth inlet flow path connected to the fourth supply line; and an outlet flow path for supplying the treatment solution from the body to the processing chamber, the second inlet flow path and the third inlet flow path are formed in parallel with the outlet flow path, the first inlet flow path includes: a first inlet part through which the first liquid is introduced from the first supply line; and a first outlet part through which the first liquid flows out into the buffer space, the fourth inlet flow path includes: a second inlet part through which the second liquid is introduced from the first supply line; and a second outlet part through which the second liquid flows out into the buffer space, the first inlet part, the second inlet part, the second inlet flow path, and the third inlet flow path are formed in parallel with the outlet flow path, the first outlet part and the second outlet part are formed to be inclined toward the outlet line, the controller controls the first to fourth valves so that flow rates of the first liquid and the fourth liquid are greater than the second liquid and the third liquid, the first liquid is deionized water at a first temperature, the second liquid is ammonium hydroxide (NH₄OH), the third liquid is hydrogen peroxide solution (H₂O₂), and the fourth liquid may be deionized water at a second temperature.

According to the exemplary embodiment of the present invention, wherein the body includes a first sidewall and a second sidewall defining the buffer space, the first sidewall is a wall facing the second sidewall, the first inlet flow path, the second inlet flow path, the third inlet flow path, and the fourth inlet flow path are formed on the first sidewall, and the outlet flow path may be formed on the second sidewall.

According to the exemplary embodiment of the present invention, wherein the first temperature is higher than those of the ammonium hydroxide and the hydrogen peroxide solution,
the second temperature is lower than those of the ammonium hydroxide and the hydrogen peroxide solution, and the may controller adjust the temperature of the treatment solution by adjusting ratios of the first liquid and the fourth liquid by controlling the first valve and the fourth valve.

According to the exemplary embodiment of the present invention, it is possible to prevent defects from occurring in a substrate processing process when a substrate is treated with a treatment solution.

In addition, according to the exemplary embodiment of the present invention, it is possible to efficiently mix a plurality of liquids.

In addition, according to the exemplary embodiment of the present invention, it is possible to stably provide the concentration of the treatment solution.

In addition, according to the exemplary embodiment of the present invention, it is possible to stably provide the temperature of the treatment solution.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating an exemplary embodiment of an existing mixing manifold.

FIG. 2 is a top plan view schematically illustrating a substrate processing apparatus according to an exemplary embodiment of the present invention.

FIG. 3 is a diagram schematically illustrating a processing unit of FIG. 2 according to an exemplary embodiment.

FIG. 4 is a diagram schematically illustrating the processing chamber of FIG. 3 according to the exemplary embodiment.

FIG. 5 is a diagram schematically illustrating a mixing manifold of FIG. 3 according to the exemplary embodiment.

FIG. 6 is a cross-sectional view illustrating a cross-section of the mixing manifold of FIG. 5.

FIG. 7 is a diagram illustrating only first to fourth inlet flow paths of the mixing manifold of FIG. 5.

FIG. 8 is a flowchart illustrating a substrate processing method according to an exemplary embodiment of the present invention.

FIG. 9 is a diagram illustrating another exemplary embodiment of a treatment solution supply unit for supplying a treatment solution to the processing chamber of FIG. 3.

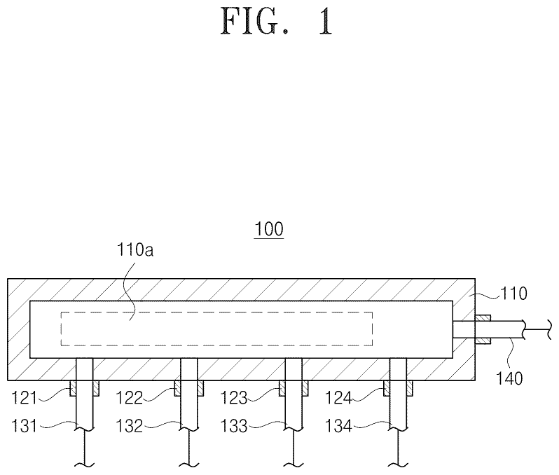

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be processed. However, the technical idea of the present invention may be applied to devices used for processing other types of substrates other than wafers as objects to be processed.

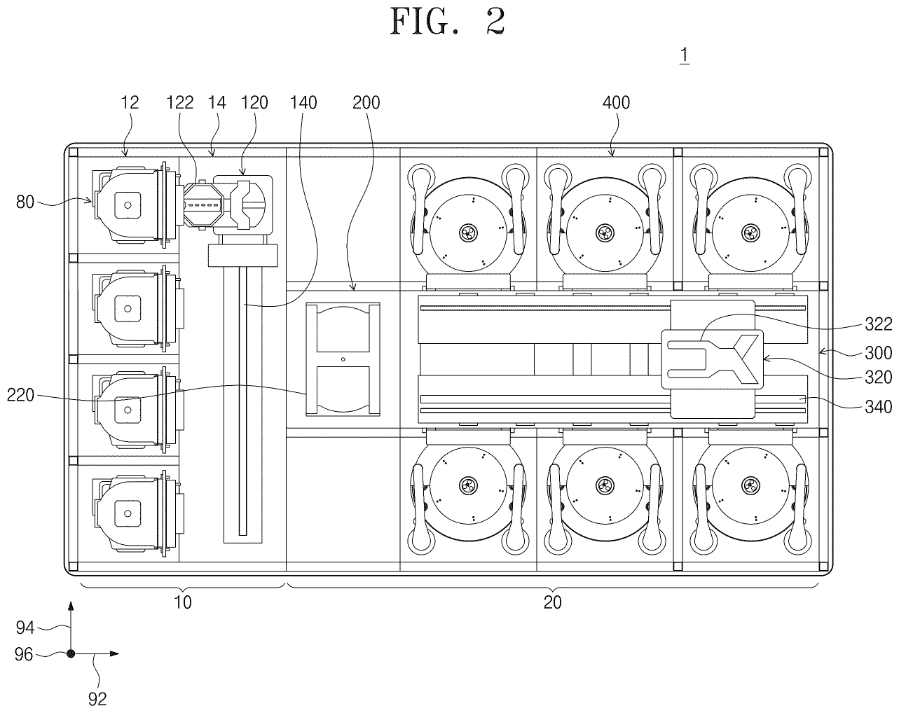

Hereinafter, an exemplary embodiment of the present invention will be described with reference to the accompanying drawings. FIG. 2 is a top plan view schematically illustrating a substrate processing apparatus according to an exemplary embodiment of the present invention. Referring to FIG. 2, a substrate processing apparatus includes an index module 10, a processing module 20, and a controller 30. According to the exemplary embodiment, the index module 10 and the processing module 20 are disposed along one direction. Hereinafter, the direction in which the index module 10 and the processing module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the processing module 20, and makes the substrate W, which has been completely processed in the processing module 20, be accommodated in the container 80. A longitudinal direction of the index module 10 is provided in the second direction 94. The index module 10 includes a load port 12 and an index frame 14. Based on the index frame 14, the load port 12 is located at a side opposite to the processing module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The processing module 20 includes a buffer unit 200, a transfer chamber 300, and a processing unit 400. The buffer unit 200 provides a space in which the substrate W loaded into the processing module 20 and the substrate W unloaded from the processing module 20 stay temporarily. The processing unit 400 performs a treatment process of liquid-treating the substrate W by supplying a liquid onto the substrate W. The transfer chamber 300 transfers the substrate W between the buffer unit 200 and the processing unit 400.

The transfer chamber 300 may be provided so that a longitudinal direction is the first direction 92. The buffer unit 200 may be disposed between the index module 10 and the transfer unit 300. A plurality of liquid processing chambers 400 may be provided and may be disposed on the side portion of the transfer unit 300. The processing unit 400 and the transfer unit 300 may be disposed in the second direction 94. The buffer unit 200 may be located at one end of the transfer unit 300.

According to the example, the processing units 400 are respectively disposed on opposite sides of the transfer unit 300. At each of opposite sides of the transfer unit 300, the processing units 400 may be provided in an array of A×B (each of A and B is 1 or a natural number greater than 1) in the first direction 92 and the third direction 96.

The transfer unit 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer unit 300. The index robot 120 may approach the buffer unit 200 through the front face, and the transfer robot 320 may approach the buffer unit 200 through the rear face.

The processing unit 400 processes the substrate W. The processing unit 400 may treat the substrate W with a treatment solution. According to an example, the processing unit 400 may clean the substrate W through a cleaning solution.

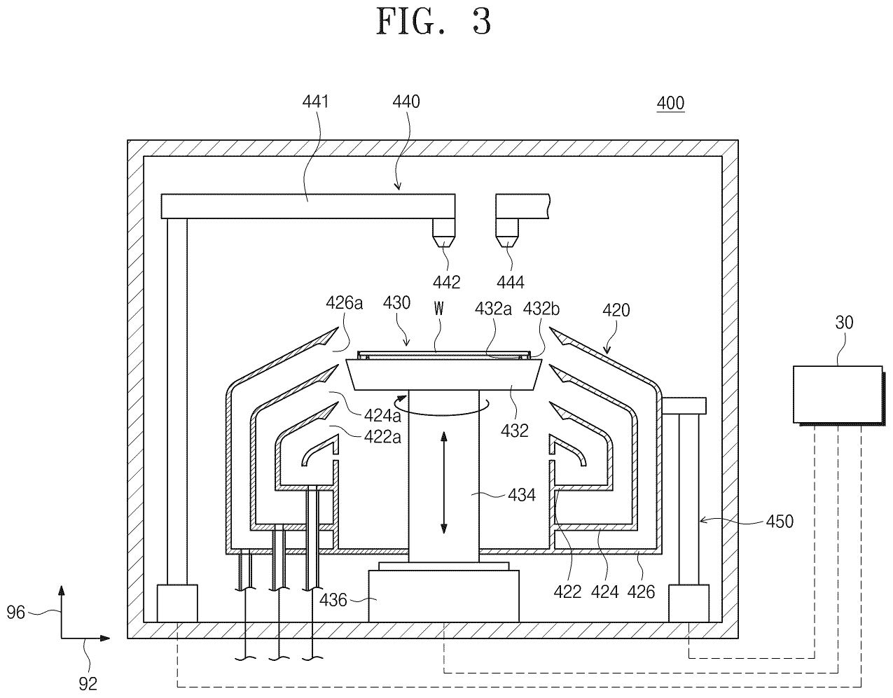

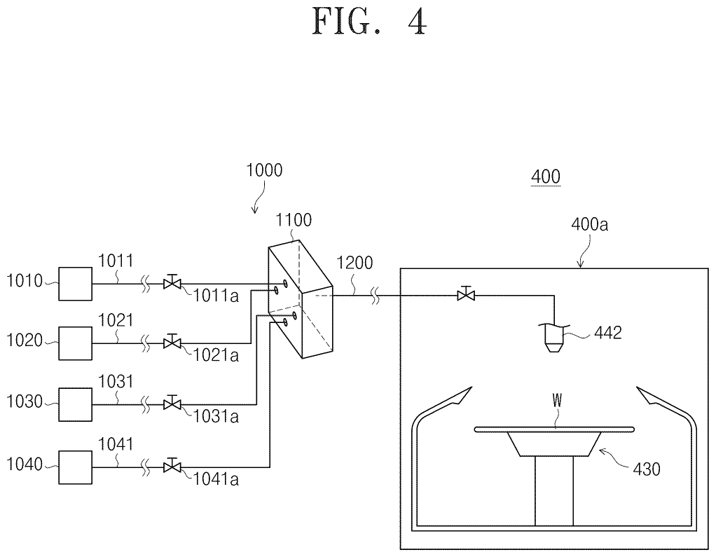

FIG. 3 is a diagram schematically illustrating the processing unit of FIG. 2 according to the exemplary embodiment, and FIG. 4 is a diagram schematically illustrating the processing chamber of FIG. 3 according to the exemplary embodiment. Referring to FIGS. 3 and 4, the processing unit 400 includes a processing chamber 400a and a treatment solution supply unit 1000. The processing chamber 400a includes a housing 410, a cup body 420, a support unit 430, a nozzle unit 440, a lifting unit 450, and a treatment solution supply unit 1000.

The housing 410 is provided in a generally rectangular parallelepiped shape. An opening (not illustrated) through which the substrate W enters and exits is formed on a sidewall of the housing 410. The opening may be opened and closed by a door (not illustrated). The cup body 420, the support unit 430, and the nozzle unit 440 are disposed within the housing 410.

The cup body 420 has a treatment space with an open top, and the substrate W is liquid-processed in the treatment space. The support unit 430 supports the substrate W in the treatment space. The nozzle unit 440 supplies the treatment solution supplied from the treatment solution supply unit 1000 onto the substrate W. The treatment solution may be supplied onto the substrate W as a mixed liquid in which a plurality of liquids is mixed. Also, as the treatment solution, a plurality of types of treatment solutions may be sequentially supplied onto the substrate W. The lifting unit 450 adjusts a relative height between the cup body 420 and the support unit 430.

According to an example, the cup body 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 430. As the liquid treating process proceeds, the treatment solution scattered by the rotation of the substrate W is introduced into the recovery space through the inlets 422a, 424a, and 426a of the respective recovery containers 422, 424, and 426. According to the example, the cup body 420 includes a first recovery container 422, a second recovery container 424, and a third recovery container 426. The first recovery container 422 is disposed to surround the support unit 430, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 430 includes a support plate 432 and a drive shaft 434. An upper surface of the support plate 432 may be provided in a generally circular shape, and may have a diameter larger than a diameter of the substrate W. Further, a support pin 432a supporting the rear surface of the substrate W is provided at the center of the support plate 432, and the upper end of the support pin 432a is provided to protrude from the support plate 432 so that the substrate W is spaced apart from the support plate 432 by a predetermined distance. A chuck pin 432b is provided at an edge of the support plate 432. The chuck pin 432b is provided to protrude upward from the support plate 432, and supports the side portion of the substrate W so that the substrate W does not deviate from the support unit 430 when the substrate W is rotated. The drive shaft 434 is driven by the driver 436, is connected to the center of the bottom surface of the substrate W, and rotates the support plate 432 about its central axis.

The nozzle unit 440 includes a first nozzle 442 and a second nozzle 444. The first nozzle 442 supplies the treatment solution onto the substrate W. The treatment solution may be a mixed liquid in which a plurality of liquids is mixed. According to an example, the treatment solution may be a Standard Clean-1 (SC-1) solution in which ammonium hydroxide (NH₄OH), hydrogen peroxide (H₂O₂) and deionized water are mixed. According to another exemplary embodiment, the treatment solution may be a mixture of chemical and deionized water. The chemical may be hydrogen fluoride (HF). Further, the second nozzle 444 supplies water onto the substrate W. The water may be pure water or deionized water.

The first nozzle 442 and the second nozzle 444 are supported by different arms 441, respectively, and these arms 441 may be moved independently. Optionally, the first nozzle 442 and the second nozzle 444 may be mounted on the same arm and moved at the same time.

Optionally, the nozzle unit 440 may further include one or a plurality of nozzles in addition to the first nozzle 442 and the second nozzle 444. The added nozzle may supply another type of treatment solution to the substrate. For example, another type of treatment solution may be an acid solution or a base solution for removing foreign substances on the substrate. In addition, another type of treatment solution may be alcohol having surface tension lower than water. For example, the alcohol may be isopropyl alcohol.

The lifting unit 450 moves the cup body 420 in the up and down direction. By the up and down movement of the cup body 420, a relative height between the cup body 420 and the substrate W is changed. Accordingly, the recovery containers 422, 424, and 426 for recovering the treatment solution are changed according to the type of liquid supplied to the substrate W, and thus the liquids may be separated and recovered. Unlike the description, the cup body 420 is fixedly installed, and the lifting unit 450 may move the support unit 430 in the vertical direction.

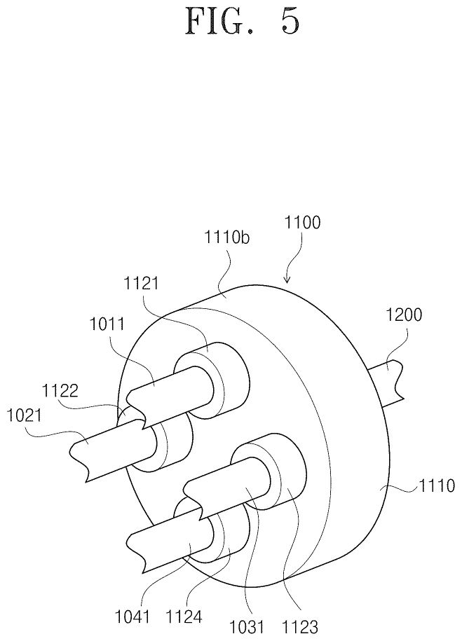

FIG. 5 is a diagram schematically illustrating the treatment solution supply unit of FIG. 3 according to the exemplary embodiment. Referring to FIG. 5, the treatment solution supply unit 1000 forms a treatment solution by mixing the first to fourth liquids and supplies the treatment solution to the first nozzle 442. The treatment solution supply unit 1000 supplies the treatment solution to the first nozzle 442. The treatment solution supply unit includes a plurality of supply sources 1010, 1020, 1030, and 1040, a plurality of supply lines 1011, 1021, 1031, and 1041, a plurality of valves 1011a, 1021a, 1031a, and 1041a, a mixing manifold 1100, and a treatment solution supply line 1200.

The first supply source 1010 stores and/or supplies a first liquid. The first supply source 1010 is coupled with the first supply line 1011. The first liquid is supplied to the mixing manifold 1100 through the first supply line 1011. Furthermore, the first liquid may be supplied at a first temperature. The first temperature may be higher than the temperatures of a second liquid and a third liquid. The first liquid may be set to the first temperature by a heater (not illustrated) installed in the first supply source 1010 or a heater (not illustrated) installed in the first supply line 1011. Furthermore, a first valve 1011a may be installed in the first supply line 1011. The first valve 1011a may adjust the flow rate of the first liquid so that the first liquid flows at a first flow rate. The first flow rate may be a flow rate greater than a second flow rate and a third flow rate. According to an example, the first liquid may include deionized water.

The second supply source 1020 stores and/or supplies the second liquid. The second supply source 1020 is coupled with the second supply line 1021. The second liquid is supplied to the mixing manifold 1100 through the second supply line 1021. Furthermore, a second valve 1021a may be installed in the second supply line 1021. The second valve 1021a may adjust the flow rate of the second liquid so that the second liquid flows at the second flow rate. The second flow rate may be a flow rate less than the first flow rate and a fourth flow rate. According to an example, the second liquid may be ammonium hydroxide (NH₄OH).

The third supply source 1030 stores and/or supplies the third liquid. The third supply source 1030 is coupled with the third supply line 1031. The third liquid is supplied to the mixing manifold 1100 through the third supply line 1031. Also, a third valve 1031a may be installed in the third supply line 1031. The third valve 1031a may adjust the flow rate of the third liquid so that the third liquid flows at the third flow rate. The third flow rate may be a flow rate less than the first flow rate and the fourth flow rate. According to an example, the third liquid may be ammonium hydroxide (NH₄OH).

The fourth supply source 1040 stores and/or supplies the fourth liquid. The fourth supply source 1040 is coupled with the fourth supply line 1041. The fourth liquid is supplied to the mixing manifold 1100 through the fourth supply line 1041. Furthermore, the fourth liquid may be supplied at a second temperature. The second temperature may be a temperature lower than the second liquid and the third liquid. The fourth liquid may be set to a fourth temperature by a cooler (not illustrated) installed in the fourth supply source 1040 or a cooler (not illustrated) installed in the fourth supply line 1041. Furthermore, the first valve 1041a may be installed in the fourth supply line 1041. The fourth valve 1041a may adjust the flow rate of the fourth liquid so that the fourth liquid flows at the fourth flow rate. The fourth flow rate may be a flow rate greater than the second flow rate and the third flow rate. According to an example, the fourth liquid may be deionized water.

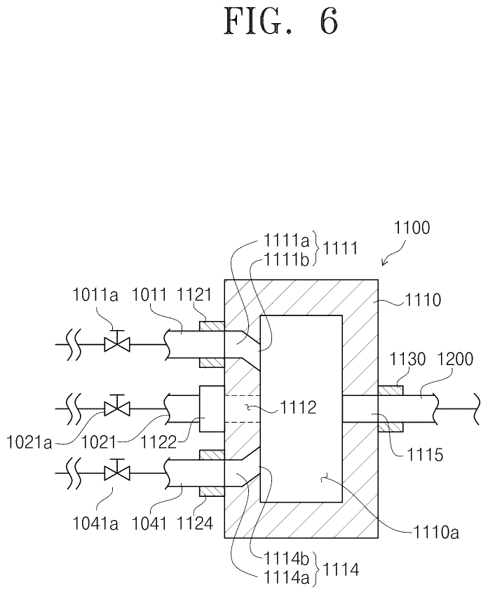

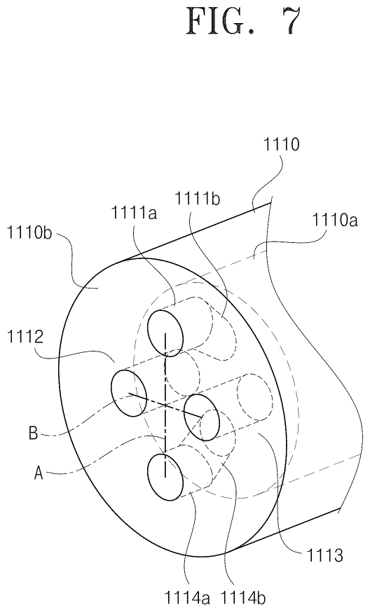

FIG. 5 is a diagram schematically illustrating the mixing manifold of FIG. 3 according to the exemplary embodiment, FIG. 6 is a cross-sectional view illustrating a cross-section of the mixing manifold of FIG. 5, and FIG. 7 is a diagram illustrating only first to fourth inlet flow paths of the mixing manifold of FIG. 5. Referring to FIGS. 5 to 7, the mixing manifold 1100 mixes the first to fourth liquids. The mixing manifold 1100 includes a body 1110, first to fourth inlet ports 1121, 1122, 1123, and 1124, and an outlet port 1130.

The body 1110 has a buffer space 1110a therein. The body 1110 includes a first sidewall 1110b and a second sidewall 1110c, and the buffer space 1110a may be defined by the first sidewall 1110b and the second sidewall 1110c.

The first sidewall 1110b and the second sidewall 1110c may be walls facing each other. The first sidewall 1110b and the second sidewall 1110c may be walls facing each other. The first sidewall 1110b and the second sidewall 1110c may be parallel to each other. First to fourth inlet lines 1111, 1112, 1113, and 1114 may be formed on the first sidewall 1110b, and an outlet line 1115 may be formed on the second sidewall 1110c. The first to fourth inlet lines 1111, 1112, 1113, and 1114 may be provided to penetrate the first sidewall 1110b. The outlet line 1115 may be provided in a shape penetrating the second sidewall 1110c. The first to fourth inlet lines 1111, 1121, 1122, and 1123 may be formed on the first sidewall 1110b, and an outlet line 1124 may be formed on the second sidewall 1110c.

The first to fourth inlet ports 1121, 1122, 1123, and 1124 are provided at positions corresponding to the first to fourth inlet lines 1111, 1112, 1113, and 1114, respectively. The outlet port 1130 is provided at a position corresponding to the outlet line 1125. The first to fourth inlet ports 1121, 1122, 1123, and 1124 are coupled to the first to fourth supply lines 1011, 1021, 1031, and 1041, respectively. The outlet port 1130 is coupled to the treatment solution supply line 1200. Accordingly, the first to fourth liquids may be introduced into the buffer space 1110a through the first to fourth inlet lines 1111, 1112, 1113, and 1114 and may be supplied from the buffer space 1110a to the treatment solution supply line 1200 through the outlet line 1115.

The first inlet line 1111 may be provided in a bent line shape. The first inlet line 1111 may include a first inlet part 1111a and a first outlet part 1111b. The first inlet part 1111a and the first outlet part 1111b communicate with each other. The first inlet part 1111a is provided to be adjacent to the first inlet port 1121. The first inlet part 1111a is provided in parallel with the second inlet line 1112, the third inlet line 1113, and the outlet line 1115. The first outlet part 1111b is provided to be adjacent to the buffer space 1110a. The first outlet part 1111b may be provided to be inclined toward the second inlet line 1112 and the third inlet line 1113. Also, the first outlet part 1111b may be provided to be inclined toward the outlet line 1115.

The fourth inlet line 1114 may be provided in a bent line shape. The fourth inlet line 1114 may include a second inlet part 1114a and a second outlet part 1114a. The second inlet part 1114a and the second outlet part 1114b communicate with each other. The second inlet part 1114a is provided to be adjacent to the fourth inlet port 1141. The second inlet part 1114a is provided in parallel with the second inlet line 1112, the third inlet line 1113, and the outlet line 1115. The second outlet part 1114b is provided to be adjacent to the buffer space 1110a. The second outlet part 1114b may be provided to be inclined toward the second inlet line 1112 and the third inlet line 1113. Also, the second outlet part 1114b may be provided to be inclined toward the outlet line 1115.

The second inlet line 1112, the third inlet line 1113, and the outlet line 1115 may be provided in a straight line shape. The second inlet line 1112, the third inlet line 1113, and the outlet line 1115 may be provided to be parallel to each other. The second inlet line 1112 and the third inlet line 1113 may be provided adjacent to each other.

The first to fourth inlet lines 1111, 1112, 1113, and 1114 may be disposed to efficiently mix the first to fourth liquids introduced into the buffer space 1110a. The first to fourth inlet lines 1111, 1112, 1113, and 1114 may be disposed in parallel with the outlet line 1115. Each of the first to fourth inlet lines 1111, 1112, 1113, and 1114 may be disposed to have the same distance from the outlet line 1115. For example, the first to fourth inlet lines 1111, 1112, 1113, and 1114 may be provided such that a virtual straight line A formed by the first inlet line 1111 and the fourth inlet line 1114 and the virtual straight line B formed by the second inlet line 1112 and the third inlet line 1113 cross each other. An angle formed by the two virtual straight lines A and B may be 90°. Also, the lengths of the two virtual straight lines A and B may be provided differently from each other. The length of the virtual straight line A may be provided to be longer than the length of the virtual straight line B.

According to the exemplary embodiment of the present invention, the first to fourth inlet lines 1111, 1112, 1113, and 1114 and the outlet line 1115 are connected in parallel. That is, the first to fourth inlet lines 1111, 1112, 1113, and 1114 are provided on the first sidewall 1110b not to be located on a straight line, and thus the distance from each of the first to fourth inlet lines 1111, 1112, 1113, and 1114 to the outlet line 1115 may be minimized. Accordingly, the residual area of the liquid supplied at a low flow rate in the buffer space 1110a may be minimized.

Furthermore, the second inlet line 1112 and the third inlet line 1113 may be provided adjacent to each other, and may be formed to have a direction parallel to the outlet line 1115. Furthermore, the second inlet line 1112 and the third inlet line 1113 may be formed adjacent to each other. Accordingly, even if a low flow rate liquid is supplied to the second inlet line 1112 and the third inlet line 1113, interference by the liquid supplied at a high flow rate may be minimized so that the low flow rate liquid may be appropriately introduced into the body 1110.

Furthermore, the first inlet line 1111 and the fourth inlet line 1114 have a curved line shape. The first inlet line 1111 and the fourth inlet line 1114 may be formed inclined toward the inside of the buffer space 1110a. Furthermore, the first inlet line 1111 and the fourth inlet line 1114 may be formed inclined toward the second liquid and the third liquid supplied through the second inlet line 1112 and the third inlet line 1113. Accordingly, the first liquid and the fourth liquid are supplied toward the second liquid and the third liquid, causing collision and rotation between the liquids, and thus mixing efficiency of a plurality of liquids may be improved, and temperature and concentration balance and stabilization of the treatment solution may be improved.

Hereinafter, a method of processing a substrate will be described. The substrate processing method described below may be performed by the substrate processing apparatus described with reference to FIGS. 2 to 7. Accordingly, hereinafter, a substrate processing method according to an exemplary embodiment will be described by referring to reference numerals illustrated in FIGS. 2 to 7. In addition, the substrate processing method described below may be performed by controlling, by the controller 30, components included in the substrate processing apparatus described above.

The controller 30 may control the entire operation of the substrate processing apparatus. The controller may include a Central Processing unit (CPU), a Read Only Memory (ROM), and a Random Access 44-16 Memory (RAM). The CPU executes desired treatment, such as etching treatment, according to various recipes stored in their storage area. In the recipe, device control information for process conditions is input. Meanwhile, these programs or recipes indicating processing conditions may be stored in a non-transitory computer-readable medium. The non-transitory computer-readable medium refers to a medium that stores data semi-permanently and is readable by a computer, rather than a medium that stores data for a short moment, such as a register, cache, and memory. Specifically, the above-described various applications or programs may be stored and provided on a non-transitory readable medium, such as a CD, DVD, hard disk, Blu-ray disk, USB, memory card, or ROM.

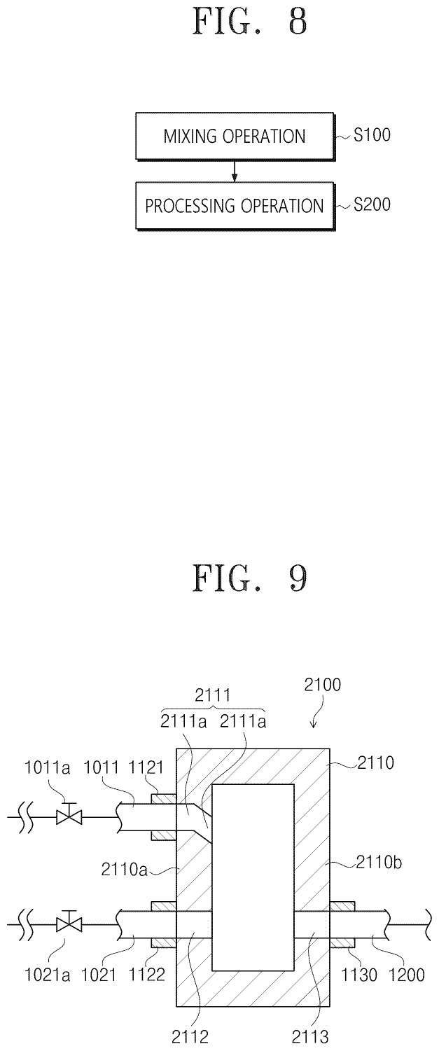

FIG. 8 is a flowchart illustrating a substrate processing method according to an exemplary embodiment of the present invention. Referring to FIG. 8, the substrate processing method may include a mixing operation S100 of forming a treatment solution by mixing a plurality of liquids, and a processing operation S200 of processing the substrate with the treatment solution.

In the mixing operation S100, a plurality of liquids is supplied to the mixing manifold 1100. A plurality of liquids may be first to fourth liquids. The controller 30 may control the first to fourth valves 1011a, 1021a, 1031a and 1041a so that the flow rates of the first liquid and the fourth liquid are greater than the flow rates of the second liquid and the third liquid. Further, in order to set a temperature of the treatment solution to a set temperature, a ratio of the flow rates of the first liquid and the fourth liquid may be adjusted by controlling the first valve 1011a and the fourth valve 1041a.

Even if the flow rates of the second liquid and the third liquid are less than the flow rates of the first liquid and the fourth liquid, the first to fourth inlet lines 1111, 1112, 1113, and 1115 are connected in parallel with the outlet lines 1115 and thus the flow paths of the first to fourth liquids may be minimized to prevent the first to fourth liquids from remaining in the mixing manifold 1100. Furthermore, since the first inlet line 1111 and the fourth inlet line 1114 are formed to be inclined toward the second liquid and the third liquid supplied through the second inlet line 1112 and the third inlet line 1113, even if the flow rates of the second liquid and the third liquid are small, the mixing efficiency of the liquid may be improved by minimizing interference by the first liquid and the fourth liquid supplied at a high flow rate. Accordingly, the mixing manifold 1100 may form a treatment solution which is a mixed liquid by mixing the first to fourth liquids.

In the processing operation S200, the treatment solution is supplied to the first nozzle 442 through the outlet line 1115, the outlet port 1130, and the treatment solution supply line 1200. The first nozzle 442 supplies the treatment solution to the substrate W supported by the support unit 430. Thereafter, the substrate W is treated by the treatment solution.

In the above-described example, the present invention has been described based on the case where the first to fourth liquids are supplied to and mixed in the mixing manifold 1100 as an example. However, the present invention is not limited thereto, and only the first to second liquids may be supplied. In this case, the mixing manifold 2100 may be provided as illustrated in FIG. 9. Hereinafter, the mixing manifold 2100 will be described with reference to FIG. 9. The same reference numerals are used for configurations overlapping the configurations described in FIGS. 2 to 7, and descriptions thereof are omitted.

FIG. 9 is a diagram illustrating another exemplary embodiment of the treatment solution supply unit for supplying a treatment solution to the processing chamber of FIG. 3. Referring to FIG. 9, the mixing manifold 2100 mixes the first liquid with the second liquid. The mixing manifold 2100 includes a body 2110 having a space therein. The body 2110 has a first sidewall 2110a and a second sidewall 2110b. The first sidewall 2110a and the second sidewall 2110b may be parallel walls. Also, the first sidewall 2110a and the second sidewall 2110b may be walls facing each other. A first inlet port 2120 and a second inlet port 2130 may be provided on the first sidewall 2110a, and an outlet port 2140 may be provided on the second sidewall 2110b. Also, a first inlet line 2111 and a second inlet line 2112 may be formed on the first sidewall 2110a, and an outlet line 21113 may be formed on the second sidewall 2110b.

The first inlet line 2111 may be provided in a bent line shape. The first inlet line 2111 may be provided in a shape penetrating the first sidewall 2110a. The first inlet line 2111 may include an inlet part 2111a and an outlet part 2111b. The inlet part 2111a may be formed parallel to the outlet line 2113. Also, the outlet part 2111b may be formed to be inclined toward the outlet line 2113. The first liquid may be introduced into the body 2110 through the first inlet line 2111. Also, the first liquid may be introduced toward the second liquid. The first liquid may collide with and rotate with the second liquid and may be mixed with the second liquid.

The second inlet line 2112 may be provided in a straight line shape. The second inlet line 2112 may be provided in a shape penetrating the first sidewall 2110a. Also, the second inlet line 2112 may be formed to be inclined toward the first liquid introduced through the first inlet line 2111. Accordingly, the second liquid may be introduced into the body 2110 through the second inlet line 2112 and may collide with and rotate with the introduced first liquid to be mixed with the first liquid. According to an example, the first liquid may be deionized water, and the second liquid may be diluted hydrofluoric acid, and a mixed liquid of the first liquid and the second liquid may be hydrogen fluoride (HF).

The controller 30 may control the first valve 1011a installed in the first supply line 1011 and the second valve 1021a installed in the second supply line 1021. According to an example, the controller 30 may control the first valve 1011a and the second valve 1021a so that the flow rate of the first liquid is greater than the flow rate of the second liquid.

The outlet line 2113 may be formed on the second sidewall 2110b. The outlet line 21113 may be provided in a straight line shape. The outlet line 2113 may be provided in a shape penetrating the second sidewall 2110b. The outlet line 2113 may be formed to have a direction parallel to the first inlet line 2111. Also, the outlet line 2113 may be provided on a straight line with the first inlet line 2111. Accordingly, even if the first liquid is supplied at a flow rate less than the second liquid, interference with introduction and discharge caused by the second liquid may be minimized.

In addition, in the above-described example, the present invention has been described based on the case where the temperature of the treatment solution is adjusted by adjusting the ratio of the flow rates of the first liquid and the fourth liquid as an example. However, the present invention is not limited thereto, and the fourth liquid may not be provided, and a temperature adjusting member (not illustrated) may be provided to the first supply source 1010 or the first supply line 1011. Accordingly, a temperature of the treatment solution may be adjusted by adjusting a temperature of the first liquid by the temperature adjusting member.

Furthermore, in the above-described example, the present invention has been described based on the case where the diameters of the first to fourth supply lines 1011, 1021, 1031, 1041 and the first to fourth inlet lines 1111, 1112, 1113, and 1114 are provided to be the same. However, the present invention is not limited thereto, and the diameters of the first supply line 1011, the fourth supply line 1041, the first inlet line 1111, and the fourth inlet line 1114 may be provided to be larger than the diameters of the second supply line 1021, the third supply line 1031, the second inlet line 1112, and the third inlet line 1113.

In addition, in the above-described example, the present invention has been described based on the case where an in-line mixer is not provided as an example. However, the present invention is not limited thereto, and an in-line mixer may be provided to the treatment solution supply line 1200.

In addition, in the above-described example, the present invention has been described based on the case where the first inlet line 1111 and the fourth inlet line 1114 are formed in a bent line shape. However, the present invention is not limited thereto, and may be provided in a straight line shape and may be provided to be inclined toward the outlet line 1115.

Also, the shape of the body 1110 is not limited to the shape illustrated in the drawing. The shape of the body 1110 is sufficient as long as the shape includes the first sidewall 1110b and the second sidewall 1110c described above.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. An apparatus for processing a substrate, the apparatus comprising:
a processing chamber for processing a substrate; and
a treatment solution supply unit for supplying a treatment solution to the processing chamber,
wherein the treatment solution supply unit includes:
a first supply line for supplying a first liquid;
a second supply line for supplying a second liquid; and
a mixing manifold for producing the treatment solution by mixing the first liquid and the second liquid; and
a treatment solution supply line for supplying the treatment solution from the mixing manifold to the processing chamber,
the mixing manifold includes a body that has a buffer space therein and is formed with a first inlet flow path, a second inlet flow path, and an outlet flow path,
the first inlet flow path connects the first supply line and the buffer space,
the second inlet flow path connects the second supply line and the buffer space,
the outlet flow path connects the buffer space and the treatment solution supply line, and
the first inlet flow path includes:
a first inlet part through which the first liquid is introduced from the first supply line; and
a first outlet part through which the first liquid flows out into the buffer space,
the inlet part and the second inlet flow path are formed parallel to the outlet flow path, and
the outlet part is formed to be inclined with respect to the outlet flow path.

2. The apparatus of claim 1, wherein the treatment solution supply unit further includes:
a first valve that is installed in the first supply line and adjusts a flow rate of the first liquid; and
a second valve that is installed in the second supply line and adjusts a flow rate of the second liquid, and
the apparatus further comprises a controller for controlling the first valve and the second valve so that the first liquid has a lower flow rate than the second liquid.

3. The apparatus of claim 2, wherein the treatment solution supply unit further includes a third supply line for supplying a third liquid,
the body is further formed with a third inlet flow path connected to the third supply line, and
the third inlet flow path is formed parallel to the outlet flow path.

4. The apparatus of claim 3, wherein the treatment solution supply unit further includes a third valve that is installed in the third supply line and adjusts a flow rate of the third liquid, and
the controller controls the third valve so that the third liquid has a lower flow rate than the first liquid.

5. The apparatus of claim 4, wherein the third inlet flow path is formed to be adjacent to the second inlet flow path.

6. The apparatus of claim 5, wherein the treatment solution supply unit further includes a fourth supply line for supplying a fourth liquid,
the body is further formed with a fourth inlet flow path connected to the fourth supply line, and
the fourth inlet flow path includes:
a second inlet part through which the fourth liquid is introduced from the fourth supply line; and
a second outlet part through which the fourth liquid flows out into the buffer space,
the second inlet part is formed parallel to the outlet flow path, and
the first outlet part and the second outlet part are formed to be inclined toward the outlet flow path.

7. The apparatus of claim 6, wherein the treatment solution supply unit further includes a fourth valve that is installed in the fourth supply line and adjusts a flow rate of the fourth liquid, and
the controller controls the fourth valve so that the fourth liquid has a lower flow rate than the third liquid.

8. The apparatus of claim 7, wherein the body includes a first sidewall and a second sidewall defining the buffer space,
the first sidewall is a wall facing the second sidewall,
the first inlet flow path, the second inlet flow path, the third inlet flow path, and the fourth inlet flow path are formed on the first sidewall, and
the outlet flow path is formed on the second sidewall.

9. The apparatus of claim 2, wherein the first liquid is deionized water, and the second liquid is chemical.

10. The apparatus of claim 9, wherein the chemical is hydrogen fluoride.

11. The apparatus of claim 7, wherein the first liquid and the fourth liquid are deionized water,
the second liquid is ammonium hydroxide (NH₄OH),
the third liquid is hydrogen peroxide solution (H₂O₂), and
the fourth liquid has a higher temperature than the first liquid.

12. An apparatus for processing a substrate, the apparatus comprising:
a processing chamber for processing a substrate; and
a treatment solution supply unit for supplying a treatment solution to the processing chamber,
wherein the treatment solution supply unit includes:
a first supply line for supplying deionized water;
a second supply line for supplying ammonium hydroxide;
a third supply line for supplying hydrogen peroxide solution; and
a mixing manifold for producing the treatment solution by mixing the deionized water, the ammonium hydroxide, and the hydrogen peroxide solution; and
a treatment solution supply line for supplying the treatment solution from the mixing manifold to the processing chamber, and
the mixing manifold includes a body that has a buffer space therein and is formed with a first inlet flow path, a second inlet flow path, a third inlet flow path, and an outlet flow path,
the first inlet flow path connects the first supply line and the buffer space,
the second inlet flow path connects the second supply line and the buffer space,
the third inlet flow path connects the third supply line and the buffer space,
the outlet flow path connects the buffer space and the treatment solution supply line, and
the first inlet flow path includes:
a first inlet part through which the deionized water is introduced from the first supply line; and
a first outlet part through which the deionized water flows out into the buffer space,
the inlet unit, the second inlet flow path, and the third inlet flow path are formed in parallel with the outlet flow path, and
the outlet part is formed to be inclined with respect to the outlet flow path.

13. The apparatus of claim 12, further comprising:
a controller,
wherein the treatment solution supply unit includes:
a first valve that is installed in the first supply line and adjusts a flow rate of the deionized water;
a second valve that is installed in the second supply line and adjusts a flow rate of the ammonium hydroxide; and
a third valve that is installed in the third supply line and adjusts a flow rate of the hydrogen peroxide solution, and
the controller controls the first valve, the second valve, and the third valve so that a flow rate of the deionized water is greater than the ammonium hydroxide and the hydrogen peroxide solution.

14. The apparatus of claim 13, wherein the third inlet line and the second inlet line are formed adjacent to each other.

15. The apparatus of claim 14, wherein the body includes a first sidewall and a second sidewall defining the buffer space,
the first sidewall is a wall facing the second sidewall,
the first inlet flow path, the second inlet flow path, and the third inlet flow path are formed on the first sidewall, and
the outlet flow path is formed on the second sidewall.

16. The apparatus of claim 15, wherein distances between the first inlet line, the second inlet line, and the third inlet line and the outlet line are provided equally.

17. The apparatus of claim 16, wherein the treatment solution supply unit further includes a temperature adjusting member that adjusts a temperature of the deionized water, and
the controller controls a temperature of the treatment solution by adjusting the temperature of the deionized water by controlling the temperature adjusting member.

18. An apparatus for processing a substrate, the apparatus comprising:
a processing chamber for processing a substrate;
a treatment solution supply unit for supplying a treatment solution to the processing chamber; and
a controller,
wherein the treatment solution supply unit includes:
a first supply line through which a first liquid is supplied, and in which a first valve is installed to adjust a flow rate of the first liquid;
a second supply line through which a second liquid is supplied, and in which a second valve is installed to adjust a flow rate of the second liquid;
a third supply line through which a third liquid is supplied, and in which a third valve is installed to adjust a flow rate of the third liquid;
a fourth supply line through which a fourth liquid is supplied, and in which a fourth valve is installed to adjust a flow rate of the fourth liquid; and
a mixing manifold connected to the first to fourth supply lines,
the mixing manifold includes a body having a space therein,
the body includes:
a first inlet flow path connected to the first supply line;
a second inlet flow path connected to the second supply line;
a third inlet flow path connected to the third supply line;
a fourth inlet flow path connected to the fourth supply line; and
an outlet flow path for supplying the treatment solution from the body to the processing chamber,
the second inlet flow path and the third inlet flow path are formed in parallel with the outlet flow path,
the first inlet flow path includes:
a first inlet part through which the first liquid is introduced from the first supply line; and
a first outlet part through which the first liquid flows out into the buffer space,
the fourth inlet flow path includes:
a second inlet part through which the second liquid is introduced from the first supply line; and
a second outlet part through which the second liquid flows out into the buffer space,
the first inlet part, the second inlet part, the second inlet flow path, and the third inlet flow path are formed in parallel with the outlet flow path,
the first outlet part and the second outlet part are formed to be inclined toward the outlet line,
the controller controls the first to fourth valves so that flow rates of the first liquid and the fourth liquid are greater than the second liquid and the third liquid,
the first liquid is deionized water at a first temperature,
the second liquid is ammonium hydroxide (NH₄OH),
the third liquid is hydrogen peroxide solution (H₂O₂), and
the fourth liquid is deionized water at a second temperature.

19. The apparatus of claim 18, wherein the body includes a first sidewall and a second sidewall defining the buffer space,
the first sidewall is a wall facing the second sidewall,
the first inlet flow path, the second inlet flow path, the third inlet flow path, and the fourth inlet flow path are formed on the first sidewall, and
the outlet flow path is formed on the second sidewall.

20. The apparatus of claim 19, wherein the first temperature is higher than those of the ammonium hydroxide and the hydrogen peroxide solution,
the second temperature is lower than those of the ammonium hydroxide and the hydrogen peroxide solution, and
the controller adjust the temperature of the treatment solution by adjusting ratios of the first liquid and the fourth liquid by controlling the first valve and the fourth valve.
